(19) United States
(12) Patent Application Publication
(10) Pub. No.: US 2024/0404998 A1
(43) Pub. Date: Dec. 5, 2024

(54) COVER STRUCTURE FOR BEAMSHAPING FOR LIGHT EMITTING DIODE PACKAGES

(71) Applicant: CreeLED, Inc., Durham, NC (US)

(72) Inventors: Robert Wilcox, Rolesville, NC (US); Cherif Ghoul, Raleigh, NC (US); Colin Blakely, Raleigh, NC (US)

(21) Appl. No.: 18/203,868

(22) Filed: May 31, 2023

(51) Int. Cl. H01L 25/075

(52) U.S. Cl. CPC H01L 25/0753

(57) ABSTRACT

Solid-state lighting devices, and more particularly, cover structures for beamshaping for multi-chip light emitting diode (LED) components are disclosed. The cover structure can reduce the far field emission pattern variation due to having different light emission sources on a multi-chip LED component. The cover structure can include channels, or tunnels, within an otherwise light-transmissive material that perform beamshaping of at least a portion of the light emitted from the multiple LED chips. The beamshaping can be a result of a predetermined orientation and/or distribution pattern of the channels that redirect the light. The cover structure can also include textured surfaces or light-altering materials that can further diffuse the light emitted from the multi-chip LED component.

### FIELD OF THE DISCLOSURE

The present disclosure relates to a solid-state lighting device, and more particularly to a cover structure for beamshaping for light emitting diode (LED) packages.

### BACKGROUND

Solid-state lighting devices such as light-emitting diodes (LEDs) are increasingly used in both consumer and commercial applications.

Advancements in LED technology have resulted in highly efficient and mechanically robust light sources with a long service life. Accordingly, modern LEDs have enabled a variety of new display applications and are being increasingly utilized for general illumination and automotive applications, often replacing incandescent and fluorescent light sources.

LEDs are solid-state devices that convert electrical energy to light and generally include one or more active layers of semiconductor material (or an active region) arranged between oppositely doped n-type and p-type layers.

When a bias is applied across the doped layers, holes and electrons are injected into the one or more active layers where they recombine to generate emissions such as visible light or ultraviolet emissions. An LED chip typically includes an active region that may be fabricated, for example, from silicon carbide, gallium nitride, gallium phosphide, aluminum nitride, gallium arsenide-based materials, and/or from organic semiconductor materials. Photons generated by the active region are initiated in all directions.

The art continues to seek improved LEDs and solid-state lighting devices having desirable illumination characteristics capable of overcoming challenges associated with conventional lighting devices.

### SUMMARY

The present disclosure relates to a solid-state lighting device, and more particularly to a cover structure for beamshaping for multi-chip light emitting diode (LED) components. The cover structure can reduce the far field emission pattern variation due to having different light emission sources on a multi-chip LED component. The cover structure can include channels, or tunnels, within an otherwise light-transmissive material that perform beamshaping of at least a portion of the light emitted from the multiple LED chips. The beamshaping can be a result of a predetermined orientation and/or distribution pattern of the channels that redirect the light. The cover structure can also include textured surfaces or light-altering materials that can further diffuse the light emitted from the multi-chip LED component.

In an embodiment, a cover structure can be provided that includes a plurality of channels that pass through at least a portion of a distance between a top of the cover structure and a bottom of the cover structure, wherein the cover structure modifies an emission pattern of light emitted from a light source at a bottom of the cover structure.

In an embodiment, the cover structure is mounted over at least a portion of each LED chip of a plurality of LED chips that are mounted on a substrate.

In an embodiment, wherein the plurality of channels are open to at least one of the top of the cover structure or the bottom of the cover structure.

In an embodiment, the plurality of channels are cylindrical.

In an embodiment, a channel diameter of the plurality of channels is between 1 micron and 1 millimeter.

In an embodiment, the plurality of channels have a distribution or orientation so as to reduce a variation in a far-field emission pattern caused by separation between the plurality of LED chips.

In an embodiment, the plurality of channels have a distribution pattern within the cover structure with a higher density over an area of the substrate between the plurality of LED chips.

In an embodiment, the plurality of channels have a distribution pattern within the cover structure with a density that corresponds to a distance from an edge of the cover structure.

In an embodiment, the plurality of channels are oriented such that a top of respective channels is closer to a center of the cover structure than a bottom of the respective channels.

In an embodiment, the cover structure covers a top of the plurality of LED chips.

In an embodiment, the cover structure has a curved top surface.

In an embodiment, the cover structure further comprises a lens covering the cover structure.

In an embodiment, the lens comprises diffusion material.

In an embodiment, the lens comprises a wavelength conversion material.

In an embodiment, the cover structure comprises a wavelength conversion material.

In an embodiment, the cover structure comprises a textured surface with a plurality of regular or irregular light-extraction features.

In an embodiment, the diffusion material is formed in a layer within the cover structure.

In an embodiment, the cover structure is formed from at least one of sapphire, glass, silicone, or indium tin oxide.

In an embodiment, an LED component is provided that includes a plurality of LED chips mounted on a substrate and a cover structure mounted over at least a portion of each LED chip of the plurality of LED chips, wherein the cover structure comprises a plurality of channels that pass through at least a portion of a distance between a top of the cover structure and a bottom of the cover structure and wherein the plurality of channels are configured to modify an emission pattern of light emitted from the plurality of LED chips.

In another aspect, any of the foregoing aspects individually or together, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1A is an example of a conventional multi-chip light emitting diode (LED) component.

FIG. 1B is an example of a light emission pattern from a conventional multi-chip LED component.

FIG. 2A is an example of a multi-chip LED component with a cover structure for beamforming according to an embodiment of the present disclosure.

FIG. 2B is an example of a light emission pattern from a multi-chip LED component with a cover structure for beamforming according to an embodiment of the present disclosure.

FIG. 3 is an example of a multi-chip LED component with a cover structure in a different orientation according to an embodiment of the present disclosure.

FIG. 4 is an example of a multi-chip LED component with a circular cover structure according to an embodiment of the present disclosure.

FIG. 5 is an example of a cover structure with channels according to an embodiment of the present disclosure.

FIG. 6 is an example of a cover structure with channels in a defined distribution pattern according to an embodiment of the present disclosure.

FIG. 7 is an example of a cover structure with channels in a defined orientation according to an embodiment of the present disclosure.

FIG. 8 is an example of a cover structure with channels that are exposed to a bottom of the cover structure according to an embodiment of the present disclosure.

FIG. 9 is an example of a cover structure with channels that are exposed to a top of the cover structure according to an embodiment of the present disclosure.

FIG. 10 is an example of a cover structure with channels and diffusion material according to an embodiment of the present disclosure.

FIG. 11 is an example of a cover structure with channels and diffusion material in a layer according to an embodiment of the present disclosure.

FIG. 12 is an example of a cover structure with channels and a textured surface according to an embodiment of the present disclosure.

FIG. 13 is an example of a cover structure with oriented channels, a layer of diffusion material and a textured surface according to an embodiment of the present disclosure.

FIG. 14 is a cross-sectional view of a multi-chip LED component with a cover structure corresponding to the multi-chip LED component of FIG. 2A according to an embodiment of the present disclosure.

FIG. 15 is a cross-sectional view of a multi-chip LED component with a cover structure corresponding to the multi-chip LED component of FIG. 3 according to an embodiment of the present disclosure.

FIG. 16 is a cross-sectional view of a multi-chip LED component with a cover structure that covers all of the LED chips according to an embodiment of the present disclosure.

FIG. 17 is a cross-sectional view of a multi-chip LED component with a cover structure and lens according to an embodiment of the present disclosure.

FIG. 18 is a cross-sectional view of a multi-chip LED component with a curved cover structure according to an embodiment of the present disclosure.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

The present disclosure relates to solid-state lighting device, and more particularly to a cover structure for beamshaping for multi-chip light emitting diode (LED) components. The cover structure can reduce the far field emission pattern variation due to having different light emission sources on a multi-chip LED component. The cover structure can include channels, or tunnels, within an otherwise light-transmissive material that perform beamshaping of at least a portion of the light emitted from the multiple LED chips. The beamshaping can be a result of a predetermined orientation and/or distribution pattern of the channels that redirect the light. The cover structure can also include textured surfaces or light-altering materials that can further diffuse the light emitted from the multi-chip LED component.

An LED chip typically comprises an active LED structure or region that can have many different semiconductor layers arranged in different ways. The fabrication and operation of LEDs and their active structures are generally known in the art and are only briefly discussed herein. The layers of the active LED structure can be fabricated using known processes with a suitable process being fabrication using metal organic chemical vapor deposition. The layers of the active LED structure can comprise many different layers and generally comprise an active layer sandwiched between n-type and p-type oppositely doped epitaxial layers, all of which are formed successively on a growth substrate. It is understood that additional layers and elements can also be included in the active LED structure, including, but not limited to, buffer layers, nucleation layers, super lattice structures, un-doped layers, cladding layers, contact layers, and current-spreading layers and light extraction layers and elements. The active layer can comprise a single quantum well, a multiple quantum well, a double heterostructure, or super lattice structures.

The active LED structure can be fabricated from different material systems, with some material systems being Group III nitride-based material systems. Group III nitrides refer to those semiconductor compounds formed between nitrogen (N) and the elements in Group III of the periodic table, usually aluminum (Al), gallium (Ga), and indium (In). Gallium nitride (GaN) is a common binary compound. Group Ill nitrides also refer to ternary and quaternary compounds such as aluminum gallium nitride (AlGaN), indium gallium nitride (InGaN), and aluminum indium gallium nitride (AlInGaN). For Group III nitrides, silicon (Si) is a common n-type dopant and magnesium (Mg) is a common p-type dopant. Accordingly, the active layer, n-type layer, and p-type layer may include one or more layers of GaN, AlGaN, InGaN, and AlInGaN that are either undoped or doped with Si or Mg for a material system based on Group III nitrides. Other material systems include silicon carbide (SiC), organic semiconductor materials, and other Group III-V systems such as gallium phosphide (GaP), gallium arsenide (GaAs), and related compounds.

The active LED structure may be grown on a growth substrate that can include many materials, such as sapphire, SiC, aluminum nitride (AlN), and GaN. Sapphire is another common substrate for Group III nitrides and also has certain advantages, including being lower cost, having established manufacturing processes, and having good light-transmissive optical properties.

Different embodiments of the active LED structure can emit different wavelengths of light depending on the composition of the active layer. In some embodiments, the active LED structure emits blue light with a peak wavelength range of approximately 430 nanometers (nm) to 480 nm. In other embodiments, the active LED structure emits green light with a peak wavelength range of 500 nm to 570 nm. In other embodiments, the active LED structure emits red light with a peak wavelength range of 600 nm to 650 nm.

An LED chip can also be covered with one or more lumiphoric materials (also referred to herein as lumiphors), such as phosphors, such that at least some of the light from the LED chip is absorbed by the one or more lumiphors and is converted to one or more different wavelength spectra according to the characteristic emission from the one or more lumiphors. In this regard, at least one lumiphor receiving at least a portion of the light generated by the LED source may re-emit light having different peak wavelength than the LED source. An LED source and one or more lumiphoric materials may be selected such that their combined output results in light with one or more desired characteristics such as color, color point, intensity, etc. In certain embodiments, aggregate emissions of LED chips, optionally in combination with one or more lumiphoric materials, may be arranged to provide cool white, neutral white, or warm white light, such as within a color temperature range of from 2500K to 10,000K. In certain embodiments, lumiphoric materials having cyan, green, amber, yellow, orange, and/or red peak emission wavelengths may be used. In some embodiments, the combination of the LED chip and the one or more lumiphors (e.g., phosphors) emits a generally white combination of light. The one or more phosphors may include yellow (e.g., YAG:Ce), green (e.g., LuAg:Ce), and red (e.g., Ca_{i-x-y}SrₓEu_{y}AlSiN₃) emitting phosphors, and combinations thereof.

Lumiphoric materials as described herein may be or include one or more of a phosphor, a scintillator, a lumiphoric ink, a quantum dot material, a day glow tape, and the like. Lumiphoric materials may be provided by any suitable means, for example, direct coating on one or more surfaces of an LED, dispersal in an encapsulant material configured to cover one or more LEDs, and/or coating on one or more optical or support elements (e.g., by powder coating, inkjet printing, or the like). In certain embodiments, lumiphoric materials may be downconverting or upconverting, and combinations of both downconverting and upconverting materials may be provided. In certain embodiments, multiple different (e.g., compositionally different) lumiphoric materials arranged to produce different peak wavelengths may be arranged to receive emissions from one or more LED chips. One or more lumiphoric materials may be provided on one or more portions of an LED chip in various configurations.

Light emitted by the active layer or region of an LED chip is initiated in all directions. For directional applications, internal mirrors or external reflective surfaces may be employed to redirect as much light as possible toward a desired emission direction. Internal mirrors may include single or multiple layers. Some multi-layer mirrors include a metal reflector layer and a dielectric reflector layer, wherein the dielectric reflector layer is arranged between the metal reflector layer and a plurality of semiconductor layers. A passivation layer is arranged between the metal reflector layer and first and second electrical contacts, wherein the first electrical contact is arranged in conductive electrical communication with a first semiconductor layer, and the second electrical contact is arranged in conductive electrical communication with a second semiconductor layer. For single or multi-layer mirrors including surfaces exhibiting less than 100% reflectivity, some light may be absorbed by the mirror. Additionally, light that is redirected through the active LED structure may be absorbed by other layers or elements within the LED chip.

As used herein, a layer or region of a light-emitting device may be considered to be “transparent” when at least 80% of emitted radiation that impinges on the layer or region emerges through the layer or region. Moreover, as used herein, a layer or region of an LED is considered to be “reflective” or embody a “mirror” or a “reflector” when at least 80% of the emitted radiation that impinges on the layer or region is reflected. In some embodiments, the emitted radiation comprises visible light such as blue and/or green LEDs with or without lumiphoric materials. In other embodiments, the emitted radiation may comprise nonvisible light. For example, in the context of GaN-based blue and/or green LEDs, silver (Ag) may be considered a reflective material (e.g., at least 80% reflective). In the case of ultraviolet (UV) LEDs, appropriate materials may be selected to provide a desired, and in some embodiments high, reflectivity and/or a desired, and in some embodiments low, absorption. In certain embodiments, a “light-transmissive” material may be configured to transmit at least 50% of emitted radiation of a desired wavelength.

The present disclosure can be useful for LED chips having a variety of geometries, such as vertical geometry or lateral geometry. A vertical geometry LED chip typically includes anode and cathode connections on opposing sides or faces of the LED chip. A lateral geometry LED chip typically includes both anode and cathode connections on the same side of the LED chip that is opposite a substrate, such as a growth substrate. In certain embodiments, a lateral geometry LED chip may be arranged for flip-chip mounting on another surface.

As used herein, light-altering materials may include many different materials including light-reflective materials that reflect or redirect light, light-absorbing materials that absorb light, and materials that act as a thixotropic agent. As used herein, the term “light-reflective” refers to materials or particles that reflect, refract, or otherwise redirect light. For light-reflective materials, the light-altering material may include at least one of fused silica, fumed silica, titanium dioxide (TiO₂), or metal particles suspended in a binder, such as silicone or epoxy. For light-absorbing materials, the light-altering material may include at least one of carbon, silicon, or metal particles suspended in a binder, such as silicone or epoxy. The light-reflective materials and the light-absorbing materials may comprise nanoparticles. In certain embodiments, the light-altering material may comprise a generally white color to reflect and redirect light. In other embodiments, the light-altering material may comprise a generally opaque or black color for absorbing light and increasing contrast.

In certain embodiments, the light-altering material includes both light-reflective material and light-absorbing material suspended in a binder. A weight ratio of the light-reflective material to the binder may comprise a range of about 1:1 to about 2:1. A weight ratio of the light-absorbing material to the binder may comprise a range of about 1:400 to about 1:10. In certain embodiments, a total weight of the light-altering material includes any combination of the binder, the light-reflective material, and the light-absorbing material. In some embodiments, the binder may comprise a weight percent that is in a range of about 10% to about 90% of the total weight of the light-altering material. The light-reflective material may comprise a weight percent that is in a range of about 10% to about 90% of the total weight of the light-altering material. The light-absorbing material may comprise a weight percent that is in a range of about 0% to about 15% of the total weight of the light-altering material.

In certain applications, LED devices as disclosed herein may be well suited in closely-spaced array applications such automotive lighting, general lighting, and lighting displays. For exterior automotive lighting, multiple LED devices may be arranged under a common lens or optic to provide a single overall emission or emissions that are capable of changing between different emission characteristics. Changing emission characteristics may include toggling between high beam and low beam emissions, adaptively changing emissions, and adjusting correlated color temperatures (CCTs) that correspond with daytime and nighttime running conditions. In general lighting applications, LED devices as disclosed herein may be configured to provide modules, systems, and fixtures that are capable of providing one or more different emission colors or CCT values, such as one or more of warm white (e.g., 2700 Kelvin (K)-3000 K), neutral white (e.g., 3500 K-4500 K), and cool white (5000 K-6500 K). For horticulture lighting applications, LED devices as disclosed herein may be arranged to provide modules, systems, and fixtures that are capable of changing between different emission characteristics that target various growth conditions of different crops.

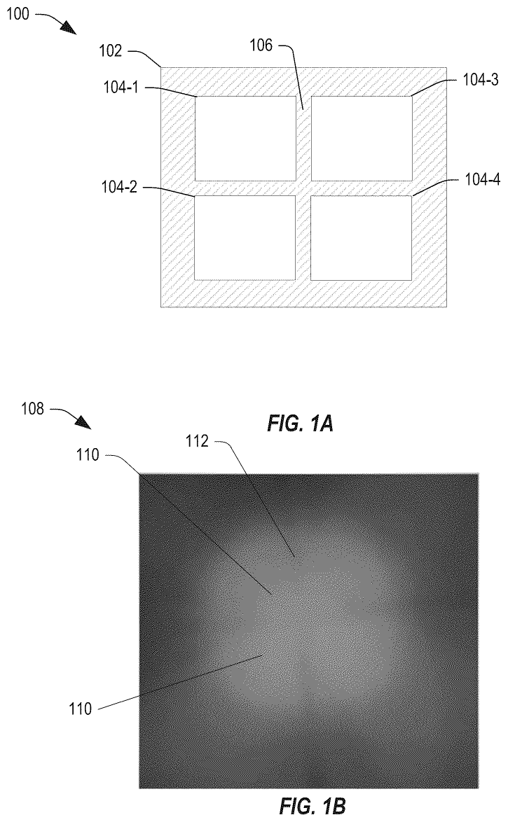

Multi-chip LED components can include a plurality of LED chips mounted on a substrate. When viewed from a typical viewing distance, due to the separation between each LED chip of the plurality of LED chips, the different LED chips can be distinguished. An example of this can be seen in a current example of a multi-LED LED component 100 in FIG. 1A, where LED chips 104-1, 104-2, 104-3, and 104-4 are mounted on a substrate 102. The gap 106 between the LED chips can be visible as dark region 112 amidst light regions 110 in FIG. 1B, which depicts an emission pattern 108 of the LED component 100. These dark regions are generally undesirable, and it can be difficult to remove or minimize the dark regions by lenses, other optics, and the LED chips 104 cannot generally be moved closer together due to heat dissipation, wiring, and other practical difficulties.

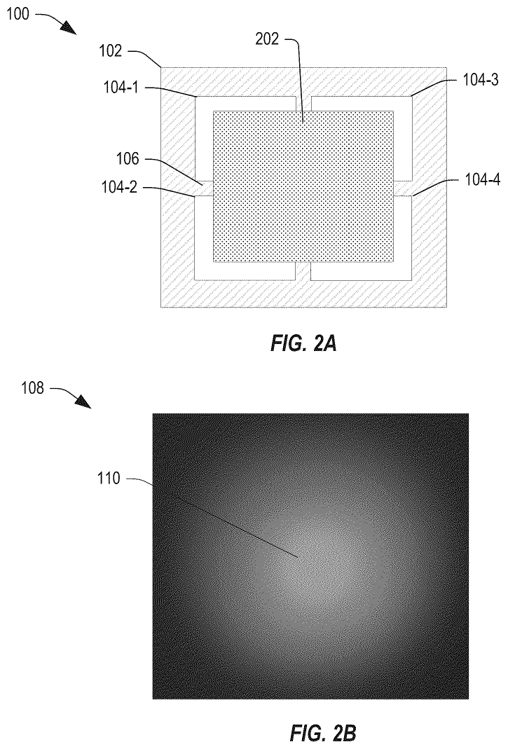

FIG. 2A is an example of a multi-chip LED component 100 with a cover structure 202 for beamforming according to an embodiment of the present disclosure. The multi-chip LED component 100 depicted in FIG. 2A is similar to the multi-chip component 100 depicted in FIG. 1A, with a substrate 102 upon which a plurality of LED chips 104-1, 104-2, 104-3, and 104-4 (collectively “LED chips 104”) are mounted. In addition however, a cover structure 202 can be mounted over the top of the LED chips 104 that can beamshape light emitted by the LED chips 104 such that instead of the emission pattern seen in FIG. 1B, the emission pattern 108 shown in FIG. 2B shows just a single source of light 110 that doesn't have the dark regions 112 from FIG. 2B that correspond to the gaps 106 between the LED chips 104. The cover structure 202 can be formed from glass, sapphire, epoxy, indium tin oxide, epoxy or other light transmissive material.

The cover structure 202 can be placed over at least a portion of each LED chip of the plurality of LED chips 104 and redirect or spread some of the light emitted by the LED chips 104 so that it appears the light is coming from areas over the gap 106 between the LED chips 104. In the embodiment shown in FIG. 2A, the cover structure 202 covers a majority of the tops of the LED chips 104, but in other embodiments, the cover structure 202 can cover less than half of the LED chips 104, or completely cover the LED chips 104 (see for example, FIG. 16).

In the embodiment shown in FIG. 2A, there are four LED chips 104, but in other embodiments, LED component 100 can include any number of LED chips. The cover structure 202 can be used to improve the light emission profile of any multi-chip LED component by removing dark regions that correspond to the gaps between the LED chips on the LED component.

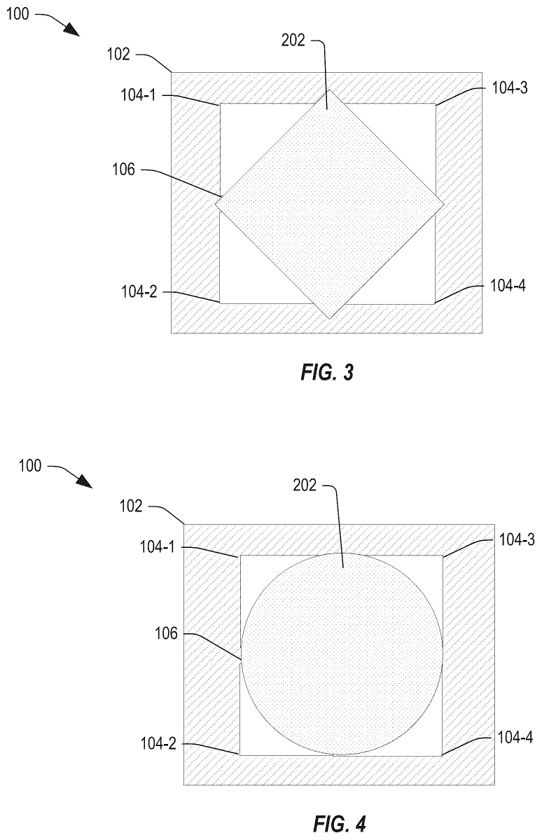

FIG. 3 is an example of a multi-chip LED component 100 with a cover structure 202 in a different orientation according to an embodiment of the present disclosure. The cover structure 202 can be rotated with the corners of the cover structure over the openings of the gaps 106 in order to increase the coverage over the gap 106, while not substantively changing the size of the cover structure 202. In other embodiments, such as in FIG. 4, the cover structure can be circular or elliptical. In other embodiments, any such shape and orientation of the cover structure relative to the LED component 100 is possible.

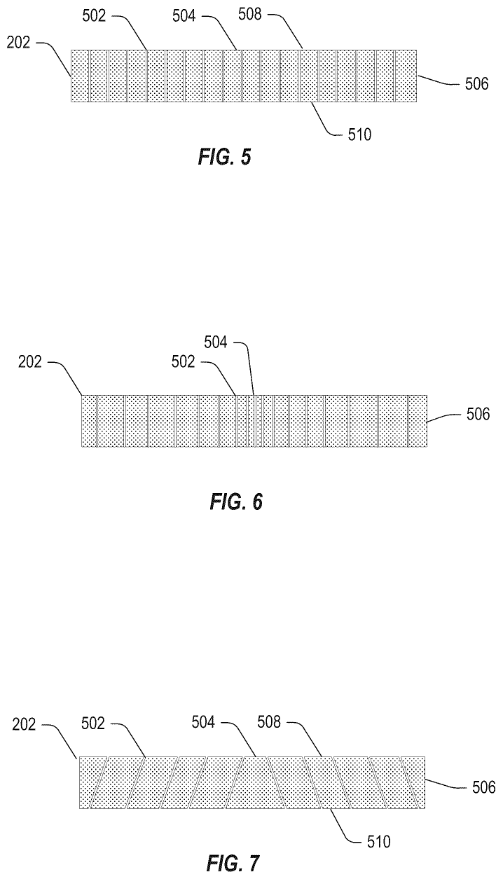

FIG. 5 is a cross sectional view of a cover structure 202 with channels according to an embodiment of the present disclosure. It is to be appreciated that the cover structure 202 can comprise one or more channels. Additionally, although only one channel is labeled in the figures, it is to be appreciated that a reference to “channel 502” or “channels 502” can be a reference to a plurality of channels in the cover structure 202.

The channels 502 in cover structure 202 can be cylindrical voids, tubes, or holes within the cover structure 202 that are formed by laser or mechanical drilling/etching and can extend through from a top 508 of the cover structure through to a bottom 510 of the cover structure such that channels 502 are exposed at both the bottom 510 and top 508 of the cover structure. The diameter of the channels can be between 1 micron and 1 mm. The channels 502 can change the emission profile of the LED component 100 by providing a path for light to transmit without an intensity drop due to any dissipation/diffusion through the material of the cover structure. Although the cover structure 202 may be mostly light-transmissive, it is to be appreciated that small amounts of light-absorption may still occur, and that light passing through the channels 502 will not be absorbed to the same degree as the light that passes through the material of the cover structure 202. The light passing through the channels 502 can either pass through directly without reflecting off the walls of the channels 502, or light incident in the channels at a bottom surface 510 at an angle can reflect one or more times off the surface of the channels 502 before exiting at the top surface 508.

It is to be appreciated that while FIG. 5 is a cross-sectional view showing an even distribution of the channels 502 in the center 504 of the cover structure 202 and outer end 506 of the cover structure 202, in other embodiments, such as the embodiment in FIG. 6, the channels 502 can be more densely distributed in the center 504 of the cover structure 202 relative to the outer end 506 of the cover structure 202. The increased density of the channels 502 in the center 504 can increase the amount of light being emitted via the cover structure 202 near the center 504 of the cover structure 202.

In an embodiment, the density variation can be two dimensional as well, with an increased density in a center in two orthogonal planes. For example, as the gap 106 in a four chip multi-chip LED component can form a cross as shown in FIG. 1A, the cover structure 202 can have an increased density of channels 502 in a similar cross shape so as to reduce the dark regions caused by the gap 106. The density distribution relative to a geometry of the cover structure 202 can be dependent on whether the cover structure 202 is placed over the LED chips 104 as shown in FIG. 2A, or rotated 90 degrees as shown in FIG. 3.

Alternatively, or in addition to the varying densities of the channels 502, the channels 502 can be oriented or at an angle as shown in FIG. 7 such that an opening on the top end 508 is close to a center 504 of the cover structure 202 than an opening of the channel is on the bottom end 510 of the cover structure 202. The effect of channels 502 oriented in this way can cause an increase in the intensity of light emitted near a center of the multi-chip LED component 100, thus reducing the dark regions 112 caused by the gap 106 between the LED chips 104. As described with reference to FIG. 6, the orientation of the channels 502 towards the center can be two dimensional, in both an x-direction and an y-direction, in order to mitigate the dark regions 112 that are cross shaped. If there are different shaped gaps in other embodiments, such as multi-chip LED components with three LED chips, or distributions of LED chips, the orientations of the channels 502 can be different in order to mitigate the resulting dark regions 112.

It is also to be appreciated that any of the embodiments described herein, both in FIGS. 5-7 and in other Figures, are additive, where embodiments can include features shown in one or more of the embodiments. For example, in an embodiment, a cover structure 202 can include channels 502 that are both oriented as in FIG. 7, and have varying density distributions as in FIG. 6.

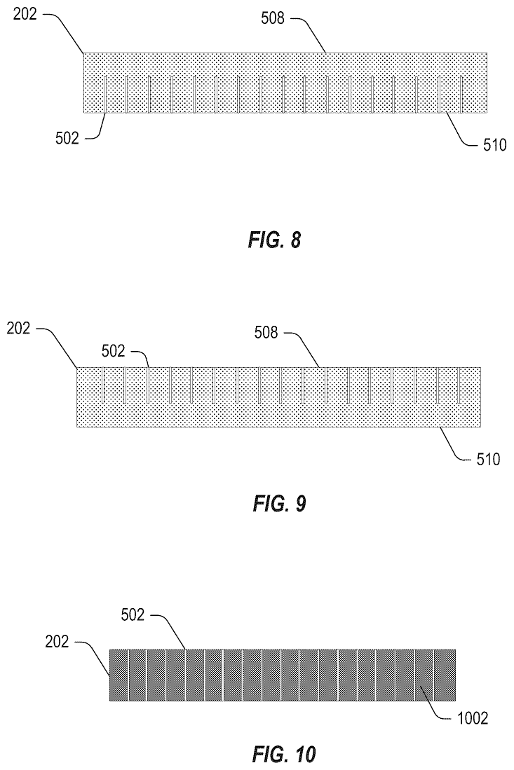

FIG. 8 is an example of a cover structure 202 with channels 502 that are exposed to a bottom 510 of the cover structure 202 and not to a top 508 of the cover structure 202. Likewise, in an alternate embodiment in FIG. 9, the channels 502 are open to the top 508 of the cover structure 202 and not the bottom 510 of the cover structure 202. The choice of whether to employ the variation in FIG. 8 or in FIG. 9 can be based on the desired emission profile.

FIG. 10 is an example of a cover structure 202 with channels 502 and diffusion material 1002 according to an embodiment of the present disclosure. The diffusion material 1002 can be a light-altering material that can diffuse light. In an embodiment, the diffusion material 1002 can be fused silica, fumed silica, titanium dioxide (TiO₂), or metal particles suspended throughout the material of the cover structure 202. In certain embodiments, the diffusion material may comprise a generally white color to reflect and redirect light. In other embodiments, the cover structure 202 can include a wavelength conversion material such as a lumiphoric material that can modify a wavelength of light emitted by the LED chips 104.

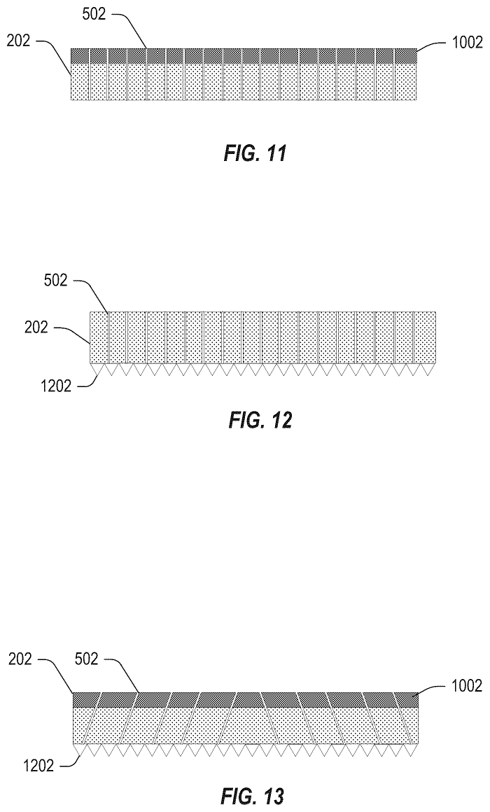

In another embodiment in FIG. 11, the diffusion material 1002 can form a distinct layer on or within the cover structure 202. For example, the diffusion material 1002 can be integral to the cover structure 202, or can be a separate layer formed on the cover structure 202. Although the embodiment in FIG. 11 shows the diffusion material 1002 being on the top of the cover structure 202, in other embodiments, the diffusion material 1002 can be in the middle, within, or on the bottom of the cover structure 202.

FIG. 12 is an example of a cover structure 202 with channels 502 and a textured surface 1202 according to an embodiment of the present disclosure. The texture surface 1202 can be on either a bottom of the cover structure 202 as depicted here in FIG. 12, or on a top of the cover structure. The textured surface can include a number of light extraction features that serve to improve the light extraction of cover structure by providing a non-smooth surface that may present surfaces at an angle such that the incidence angle of light incoming to the cover structure 202 reduces reflection. The texture surface can also cause light to scatter to a greater degree than if the surface was flat, thus obscuring the dark regions 112. The distribution of the light extraction features on the textured surface 1202 can be even, or irregular. The distribution of the light extraction features can also be defined, such as more light extraction features over the gap 106 between the LED chips 104.

FIG. 13 is an example of a cover structure 202 with oriented channels 502, a layer of diffusion material 1002 and a textured surface 1202 in an embodiment that combines the features of the embodiments depicted in FIG. 12, FIG. 11, and FIG. 7.

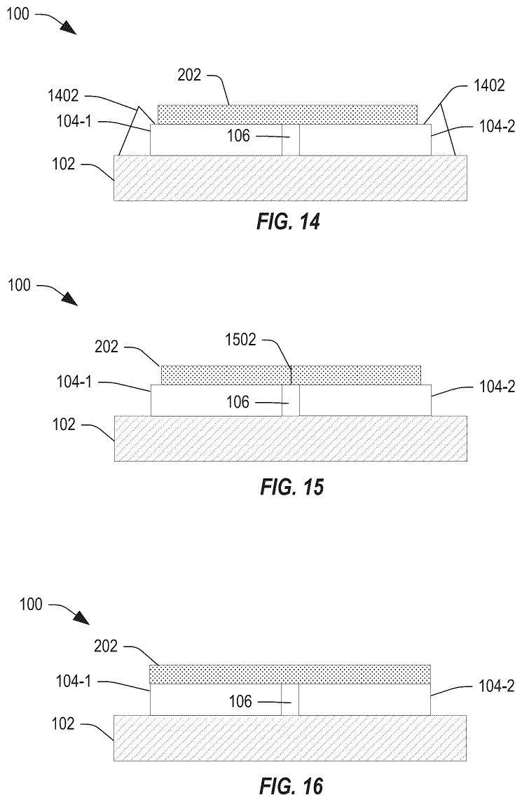

FIG. 14 is a cross-sectional view of a multi-chip LED component 100 with a cover structure 202 corresponding to the multi-chip LED component of FIG. 2A according to an embodiment of the present disclosure. One of the reasons that the cover structure 202 does not extend to the edges of the LED chips 104 is that space is left for wire bonds 1402 to be in contact with a top surface of the LED chips 104. The cover structure 202 can extend over a remainder of the surface, including over the gap 106 between the LED chips 104.

FIG. 15 is a cross-sectional view of a multi-chip LED component 100 with a rotated cover structure 202 corresponding to the multi-chip LED component 100 of FIG. 3. The corner 1502 of the cover structure 202 can be placed over an opening to the gap 106 to provide improved coverage over the gap 106 without changing the overall size of the cover structure 202 relative to the embodiment shown in FIG. 2A.

FIG. 16 is a cross-sectional view of a multi-chip LED component 100 with a cover structure 202 that covers all of the LED chips 104 according to an embodiment of the present disclosure.

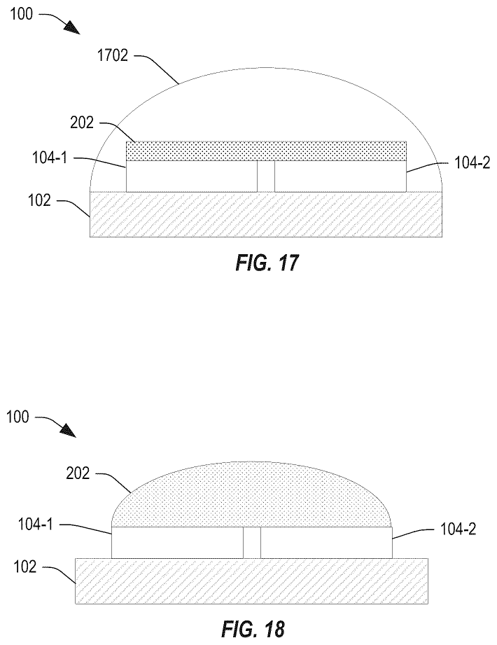

FIG. 17 is a cross-sectional view of a multi-chip LED component 100 with a cover structure 202 and lens 1702 according to an embodiment of the present disclosure. The lens 1702 can be glass or silicone and be molded over the cover structure 202 and substrate 102, or can be fixed thereto. The lens 1702 can provide further beamshaping to reduce dark regions 112 or can be for protection of the multi-chip LED component 100. In an embodiment, the lens 1702 can further include diffusion material 1002 or a wavelength conversion material to modify a wavelength of light emitted by the LED chips 104.

FIG. 18 is a cross-sectional view of a multi-chip LED component with a curved cover structure 202 according to an embodiment of the present disclosure. The curved cover structure 202 can serve to provide further beamshaping to reduce dark regions 112. It is to be appreciated that in FIGS. 14-18, the channels 502 are not depicted as in FIG. 5-10, but that is only for ease of depiction. Each of the cover structures 202 in FIGS. 14-18 can include the channels 502 to modify the light emission profile of the multi-chip LED component 100.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

What is claimed is:

1. A cover structure, comprising:
a plurality of channels that pass through at least a portion of a distance between a top of the cover structure and a bottom of the cover structure, wherein the cover structure modifies an emission pattern of light emitted from a light source at a bottom of the cover structure.

2. The cover structure of claim 1, wherein the cover structure is mounted over at least a portion of each light emitting diode (LED) chip of a plurality of LED chips that are mounted on a substrate.

3. The cover structure of claim 1, wherein the plurality of channels are open to at least one of the top of the cover structure or the bottom of the cover structure.

4. The cover structure of claim 1, wherein the plurality of channels are cylindrical.

5. The cover structure of claim 1, wherein a channel diameter of the plurality of channels is between 1 micron and 1 millimeter.

6. The cover structure of claim 2, wherein the plurality of channels have a distribution or orientation so as to reduce a variation in a far-field emission pattern caused by separation between the plurality of LED chips.

7. The cover structure of claim 2, wherein the plurality of channels have a distribution pattern within the cover structure with a higher density over an area of the substrate between the plurality of LED chips.

8. The cover structure of claim 1, wherein the plurality of channels have a distribution pattern within the cover structure with a density that corresponds to a distance from an edge of the cover structure.

9. The cover structure of claim 1, wherein the plurality of channels are oriented such that a top of respective channels is closer to a center of the cover structure than a bottom of the respective channels.

10. The cover structure of claim 2, wherein the cover structure covers a top of the plurality of LED chips.

11. The cover structure of claim 1, wherein the cover structure has a curved top surface.

12. The cover structure of claim 1, further comprising a lens covering the cover structure.

13. The cover structure of claim 12, wherein the lens comprises diffusion material.

14. The cover structure of claim 12, wherein the lens comprises a wavelength conversion material.

15. The cover structure of claim 1, wherein the cover structure comprises a wavelength conversion material.

16. The cover structure of claim 1, wherein the cover structure comprises a textured surface with a plurality of regular or irregular light-extraction features.

17. The cover structure of claim 1, wherein the cover structure comprises diffusion material that diffuses light passing through the cover structure.

18. The cover structure of claim 17, wherein the diffusion material is formed in a layer within the cover structure.

19. The cover structure of claim 1, wherein the cover structure is formed from at least one of sapphire, glass, silicone, or indium tin oxide.

20. A light emitting diode (LED) component, comprising:
a plurality of LED chips mounted on a substrate; and
a cover structure mounted over at least a portion of each LED chip of the plurality of LED chips, wherein the cover structure comprises a plurality of channels that pass through at least a portion of a distance between a top of the cover structure and a bottom of the cover structure and wherein the plurality of channels are configured to modify an emission pattern of light emitted from the plurality of LED chips.
